(19) United States
(12) Patent Application Publication
(10) Pub. No.: US 2026/0282660 A1
(43) Pub. Date: Sep. 17, 2026

(54) Display Panel, Method Of Manufacturing Display Panel, And Electronic Device Including The Same

(71) Applicant: Samsung Display Co., Ltd., Yongin-si (KR)

(72) Inventors: DONGHEE LEE, Yongin-si (KR); HEEWOON IM, Yongin-si (KR); JAE-HYUN PARK, Yongin-si (KR)

(73) Assignee: Samsung Display Co., Ltd., Yongin-si (KR)

(21) Appl. No.: 19/564,522

(22) Filed: Mar. 12, 2026

(30) Foreign Application Priority Data
Mar. 14, 2025 (KR) 10-2025-0033400

(51) Int. Cl. H10K 59/122; H10K 59/12; H10K 59/80

(52) U.S. Cl. CPC H10K 59/122; H10K 59/1201; H10K 59/879

(57) ABSTRACT

Provided is a display panel including a pixel-defining layer covering an edge of the pixel electrode and defining an emission area, barrier ribs including a first barrier layer arranged on the pixel-defining layer and a second barrier layer arranged on the first barrier layer, the barrier ribs defining a barrier opening corresponding to the emission area, a first inorganic layer arranged on the display element, and a first organic layer arranged on the first inorganic layer, wherein the second barrier layer includes a tip portion protruding in a direction from an inner surface of the first barrier layer to a center of the barrier opening, and the first inorganic layer includes an extending portion protruding further than the second barrier layer in a light-emitting direction.

### CROSS-REFERENCE TO RELATED APPLICATION

This application is based on and claims priority under 35 U.S.C. §119 to Korean Patent Application No. 10-2025-0033400, filed on Mar. 14, 2025, in the Korean Intellectual Property Office, the disclosure of which is incorporated by reference herein in its entirety.

### TECHNICAL FIELD

Aspects of the disclosure relate to a display panel, a method of manufacturing the display panel, and an electronic device including the display panel.

### BACKGROUND

Electronic devices such as smartphones, tablet computers, laptop computers, vehicle navigation systems, and smart televisions are being developed. These electronic devices include display devices to provide information.

Various types of display devices are being developed to satisfy user experience (UX)/user interface (UI) of users. Among them, the development of a flexible display device is underway. In particular, the development is underway to improve impact absorption, strength, tensile strength, and resilience in a folding area of the flexible display device.

A display device is activated according to an electrical signal. The display device may include a display panel displaying an image. With respect to the display panel, an organic light-emitting display panel has low power consumption, high brightness, and a high response speed.

Among display panels, an organic light-emitting display panel includes a pixel electrode, an opposite electrode, and an intermediate layer including an emission layer. The emission layer is separated for each emission area, and the opposite electrode provides a common voltage to each emission area.

### SUMMARY

Provided are a display panel with improved moisture permeability resistance and improved light emission efficiency, and an electronic device including the same.

Provided is a method of manufacturing the display panel.

According to an aspect of the disclosure, a display panel includes a substrate including a display area, a display element arranged in the display area and including a pixel electrode electrically connected to a thin-film transistor, an opposite electrode arranged on the pixel electrode, and an intermediate layer arranged between the pixel electrode and the opposite electrode and including an emission layer, a pixel-defining layer covering an edge of the pixel electrode and defining an emission area, barrier ribs including a first barrier layer arranged on the pixel-defining layer and a second barrier layer arranged on the first barrier layer, the barrier ribs defining a barrier opening corresponding to the emission area, a first inorganic layer arranged on the display element, and a first organic layer arranged on the first inorganic layer, wherein the second barrier layer includes a tip portion protruding in a direction from an inner surface of the first barrier layer to a center of the barrier opening, and the first inorganic layer includes an extending portion protruding further than the second barrier layer in a light-emitting direction.

In an aspect of the disclosure, the barrier ribs may include a conductive material.

In an aspect of the disclosure, the first inorganic layer may cover a lower surface and inner surface of the tip portion.

In an aspect of the disclosure, the first inorganic layer may include aluminum oxide (AlOx), hafnium oxide (HfOx), tin oxide (SnOx), zinc oxide (ZnOx), magnesium oxide (MgOx), zirconium oxide (ZrOx), silicon oxide (SiOx), or silicon nitride (SiNx).

In an aspect of the disclosure, a thickness of the first inorganic layer arranged in the emission area may be about 30 nm to about 100 nm.

In an aspect of the disclosure, a refractive index of the first organic layer may be greater than a refractive index of the first inorganic layer.

In an aspect of the disclosure, a refractive index of the first inorganic layer may be more than 1.5 but less than 1.7, and a refractive index of the first organic layer may be 1.7 or more.

In an aspect of the disclosure, the display panel may further include an auxiliary electrode arranged between the opposite electrode and the first inorganic layer.

In an aspect of the disclosure, the first organic layer may include polyimide, aryl epoxy resin, or thiophenol-based resin.

In an aspect of the disclosure, the first organic layer may protrude more than the second barrier layer and have a curved outer surface.

In an aspect of the disclosure, a scattering agent may be dispersed within the first organic layer.

In an aspect of the disclosure, the display panel may further include a second organic layer entirely covering the display area and arranged on the first organic layer, and a second inorganic layer arranged on the second organic layer.

In an aspect of the disclosure, a refractive index of the first inorganic layer may be greater than a refractive index of the second organic layer.

In an aspect of the disclosure, a refractive index of the second organic layer may be 1.5 or less.

According to another aspect of the disclosure, a method of manufacturing a display panel, includes forming a pixel-defining layer covering an edge of a pixel electrode that is arranged in a display area of a substrate, and defining an emission area, forming barrier ribs arranged on the pixel-defining layer, defining a barrier opening corresponding to the emission area, and including a first barrier layer and a second barrier layer arranged on the first barrier layer and including a tip portion protruding in a direction from an inner surface of the first barrier layer to a center of the barrier opening, sequentially forming an intermediate layer, an opposite electrode, and a first inorganic layer on the pixel electrode, and removing the intermediate layer, the opposite electrode, and the first inorganic layer formed on the barrier ribs, and forming a first organic layer filling the barrier opening, wherein, in case that the intermediate layer, the opposite electrode, and the first inorganic layer formed on the barrier ribs are removed, the first inorganic layer is formed to include an extending portion protruding further than the second barrier layer in a light-emitting direction.

In another aspect of the disclosure, the first inorganic layer may cover a lower surface and side surface of the tip portion.

In another aspect of the disclosure, the forming of the first inorganic layer may be performed using an atomic layer deposition (ALD) method.

In another aspect of the disclosure, the method may further include forming a second organic layer on the first organic layer, and forming a second inorganic layer on the second organic layer.

In an aspect of the disclosure, the forming of the second inorganic layer on the second organic layer may be performed using a chemical vapor deposition (CVD) method.

According to another aspect of the disclosure, an electronic device includes a display device including a display panel configured to generate an image, a processor, a memory, and a power module, wherein the display panel includes a substrate including a display area, a display element arranged in the display area and including a pixel electrode electrically connected to a thin-film transistor, an opposite electrode arranged on the pixel electrode, and an intermediate layer arranged between the pixel electrode and the opposite electrode and including an emission layer, a pixel-defining layer covering an edge of the pixel electrode and defining an emission area, barrier ribs including a first barrier layer arranged on the pixel-defining layer and a second barrier layer arranged on the first barrier layer, the barrier ribs defining a barrier opening corresponding to the emission area, a first inorganic layer arranged on the display element, and a first organic layer arranged on the first inorganic layer, wherein the second barrier layer includes a tip portion protruding in a direction from an inner surface of the first barrier layer to a center of the barrier opening, and the first inorganic layer includes an extending portion protruding further than the second barrier layer in a light-emitting direction.

### BRIEF DESCRIPTION OF THE DRAWINGS

The above and other aspects, features, and advantages of certain aspects of the disclosure will be more apparent from the following description taken in conjunction with the accompanying drawings in which:

FIG. 1 is a plan view schematically showing an example of a display panel, according to an aspect of the disclosure;

FIG. 2 is an enlarged plan view of a portion of a display area of a display panel, according to an aspect of the disclosure;

FIG. 3 is an equivalent circuit diagram of one pixel included in a display panel, according to an aspect of the disclosure;

FIG. 4 is a schematic cross-sectional view taken along line I-I' of FIG. 2;

FIG. 5 is a schematic cross-sectional view taken along line II-II' of FIG. 2;

FIG. 6 is another schematic cross-sectional view taken along line II-II' of FIG. 2;

FIGS. 7A to 7E are cross-sectional views schematically illustrating a method of manufacturing the display panel of FIG. 1;

FIG. 8 is a block diagram of an electronic device according to an aspect of the disclosure; and

FIG. 9 is a schematic diagram of electronic devices according to various aspects, including the display panel of FIG. 1.

### DETAILED DESCRIPTION

In the present specification, when a component (or region, a layer, a portion, or the like) is referred to as being "on," "connected to," or "coupled to" another component, it indicates that the component may be directly disposed/connected/coupled to the other component, or that a third component may be arranged between the components.

In the drawings, thicknesses, proportions, and dimensions of components may be exaggerated or reduced in sizes for effective explanation of technical content. For example, because sizes and/or thicknesses of components in the drawings are arbitrarily illustrated for convenience of explanation, the disclosure is not necessarily limited thereto.

The term "and/or" includes one or more combinations that may be defined by associated components.

While such terms as "first," "second," etc., may be used to describe various components, such components are not limited to the above terms. These terms are only used to distinguish one component from another component. For example, without departing from the scope of the rights described in the disclosure, a first component may be referred to as a second component, and similarly, a second component may be referred to as a first component.

The singular forms are intended to include the plural forms as well, unless the context clearly indicates otherwise.

The terms such as "below," "lower," "above," "on," and "upper" are used to describe relationships between components shown in the drawings. The terms are relative concepts and are explained based on directions indicated in the drawings. For example, when a portion, such as a layer, a region, or a component, is referred to as being "on" or "above" another portion, the portion may be directly on the other portion or another unit, region, or component may be present therebetween.

It is to be understood that terms such as "including" or "having", etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless otherwise defined, all terms (including technical and scientific terms) used in the present specification have the same meanings as commonly understood by one of ordinary skill in the art to which the disclosure belongs. Terms, such as those defined in commonly used dictionaries, should be interpreted as having meanings consistent with meanings in the context of relevant technology, and should not be interpreted in overly idealistic or overly formal senses, unless explicitly defined herein.

Hereinafter, aspects of the disclosure will be described in detail with reference to the accompanying drawings, and in the following description with reference to the drawings, like reference numerals refer to like or corresponding components and redundant descriptions thereof will be omitted.

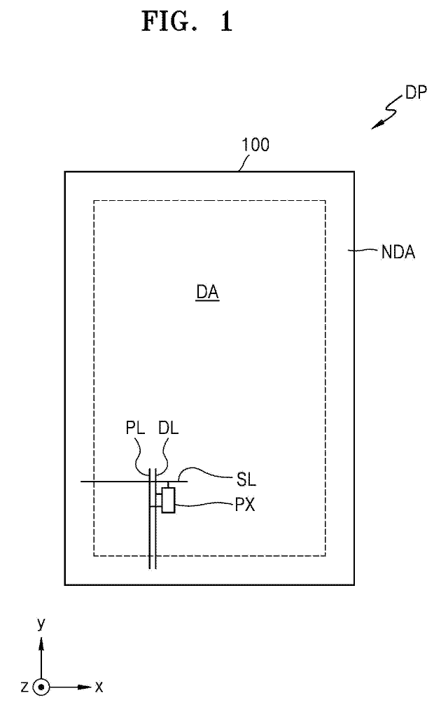

FIG. 1 is a plan view schematically showing an example of a display panel DP, according to an aspect of the disclosure.

Referring to FIG. 1, the display panel DP may include a display area DA and a non-display area NDA outside the display area DA. In FIG. 1, the display area DA is illustrated as having a rectangular shape. However, the disclosure is not limited thereto. The display area DA may have any one of various shapes, for example, a circle, an oval, a polygon, and a shape of a specific figure.

The display area DA is a portion in which an image is displayed and may include a plurality of pixels PX. The pixel PX may be embodied as a display element such as an organic light-emitting diode. Each pixel PX may emit, for example, red, green, or blue light. Such a pixel PX may be connected to a pixel circuit including a thin-film transistor (TFT), a storage capacitor, and the like. The pixel circuit may be connected to a scan line SL transmitting a scan signal, a data line DL crossing the scan line SL and transmitting a data signal, and a driving voltage line PL supplying a driving voltage. The scan line SL may extend in an x-axis direction (hereinafter, a second direction), and the data line DL and the driving voltage line PL may extend in a y-axis direction (hereinafter, a first direction).

The pixel PX may emit light of luminance corresponding to an electrical signal from the pixel circuit that is electrically connected to the pixel PX. The display area DA may display an image through light emitted from the pixel PX. For reference, the pixel PX may be defined as an emission area that emits light of any one of colors from among red, green, and blue.

The non-display area NDA is an area in which the pixel PX is not arranged, and thus may be an area in which an image is not displayed. A power supply wire driving the pixel PX may be arranged in the non-display area NDA. In some aspects, pads may be arranged in the non-display area NDA, and a printed circuit board including a driving circuit unit or an integrated circuit device such as a driver integrated circuit (IC) may be electrically connected to such a plurality of pads.

For reference, because the display panel DP includes a substrate 100, it may be said that the substrate 100 includes the display area DA and the non-display area NDA. Details about the substrate 100 will be described below.

A plurality of transistors may be arranged in the display area DA. Depending on a type (N-type or P-type) of a transistor and/or an operating condition, a first terminal of the transistor may be a source electrode or a drain electrode, and a second terminal may be an electrode different from the first terminal. For example, in case that the first terminal is a source electrode, the second terminal may be a drain electrode.

The plurality of transistors may include a driving transistor, a data write transistor, a compensation transistor, an initialization transistor, an emission control transistor, and the like. The driving transistor may be connected between the driving voltage line PL and an organic light-emitting diode OLED, and the data write transistor may be connected to the data line DL and the driving transistor and may perform a switching operation of transmitting the data signal transmitted to the data line DL.

The compensation transistor may be turned on according to the scan signal received through the scan line SL to connect the driving transistor and the organic light-emitting diode OLED to each other, thereby compensating for a threshold voltage of the driving transistor.

The initialization transistor may be turned on according to the scan signal received through the scan line SL to transmit an initialization voltage to a gate electrode of the driving transistor, thereby initializing the gate electrode of the driving transistor. A scan line connected to the initialization transistor may be a separate scan line different from a scan line connected to the compensation transistor.

The emission control transistor may be turned on according to an emission control signal received through an emission control line, and as a result, a driving current may flow in the organic light-emitting diode OLED.

The organic light-emitting diode OLED includes a pixel electrode 410 (anode) and an opposite electrode 430 (cathode), and the opposite electrode 430 may receive a second power voltage ELVSS. The organic light-emitting diode OLED may emit light by receiving the driving current from the driving transistor, thereby displaying an image.

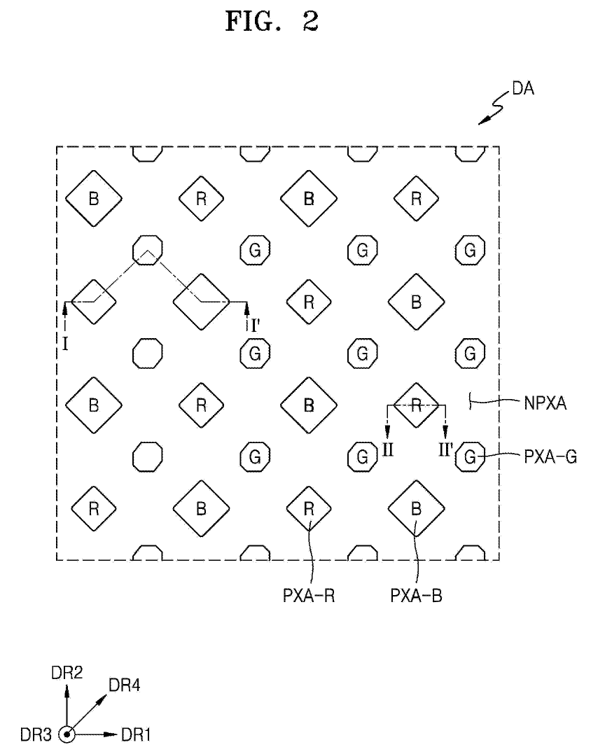

FIG. 2 is an enlarged plan view of a portion of the display area DA of the display panel DP, according to an aspect of the disclosure.

Referring to FIG. 2, the display area DA may include a first emission area PXA-R, a second emission area PXA-G, a third emission area PXA-B, and a peripheral area NPXA surrounding the first emission area PXA-R, the second emission area PXA-G, and the third emission area PXA-B. The first emission area PXA-R, the second emission area PXA-G, and the third emission area PXA-B may respectively correspond to areas where light provided from light-emitting elements ED is emitted. The first emission area PXA-R, the second emission area PXA-G, and the third emission area PXA-B may be distinguished from each other according to colors of light emitted toward the outside of a display module DM.

The first emission area PXA-R, the second emission area PXA-G, and the third emission area PXA-B may provide first color light, second color light, and third color light of different colors, respectively. For example, the first color light may be red light, the second color light may be green light, and the third color light may be blue light. However, examples of the first color light, the second color light, and the third color light are not necessarily limited thereto.

Each of the first emission area PXA-R, the second emission area PXA-G, and the third emission area PXA-B may be defined by a pixel-defining layer 250 covering an edge of the pixel electrode 410 described below. The peripheral area NPXA sets boundaries between the first emission area PXA-R, the second emission area PXA-G, and the third emission area PXA-B and may prevent color mixing between the first emission area PXA-R, the second emission area PXA-G, and the third emission area PXA-B.

Each of the first emission area PXA-R, the second emission area PXA-G, and the third emission area PXA-B may be provided in plural and may be arranged repeatedly in a selected arrangement form within the display area DA. For example, the first emission areas PXA-R and the third emission areas PXA-B may be arranged alternately along a first direction DR1 to form a "first group." The second emission areas PXA-G may be arranged along the first direction DR1 to form a "second group." Each of the "first group" and the "second group" may be provided in plural, and the "first groups" and the "second groups" may be arranged alternately along a second direction DR2.

One second emission area PXA-G may be spaced apart from one first emission area PXA-R or one third emission area PXA-B in a fourth direction DR4. The fourth direction DR4 may be defined as a direction between the first direction DR1 and the second direction DR2.

FIG. 2 illustrates an example of an arrangement of the first emission area PXA-R, the second emission area PXA-G, and the third emission area PXA-B, but the arrangement is not limited thereto and may vary. In an aspect, the first emission area PXA-R, the second emission area PXA-G, and the third emission area PXA-B may have a PENTILE^{TM} array configuration as shown in FIG. 2. In some aspects, the first emission area PXA-R, the second emission area PXA-G, and the third emission area PXA-B may have a stripe array configuration or a diamond (Diamond Pixel^{TM}) array configuration.

The first emission area PXA-R, the second emission area PXA-G, and the third emission area PXA-B may have any one of various shapes in a plan view. For example, the first emission area PXA-R, the second emission area PXA-G, and the third emission area PXA-B may have shapes such as polygons, circles, or ovals. FIG. 2 illustrates the first emission area PXA-R and the third emission area PXA-B having rectangular shapes (or rhombus shapes) and the second emission area PXA-G having an octagonal shape, in a plan view.

In a plan view, the first emission area PXA-R, the second emission area PXA-G, and the third emission area PXA-B may have a same shape or at least some thereof may have different shapes. FIG. 2 illustrates the first emission area PXA-R and the third emission area PXA-B having a same shape and the second emission area PXA-G having a different shape from the first emission area PXA-R and the third emission area PXA-B, in a plan view.

At least some of the first emission area PXA-R, the second emission area PXA-G, and the third emission area PXA-B may have different areas in plan view. In an aspect, the area of the first emission area PXA-R emitting red light may be greater than the area of the second emission area PXA-G emitting green light and less than the area of the third emission area PXA-B emitting blue light. However, relationships between the areas of the first emission area PXA-R, the second emission area PXA-G, and the third emission area PXA-B according to emitted colors are not limited thereto and may vary depending on a design of the display panel DP. An aspect is not limited thereto, and the first emission area PXA-R, the second emission area PXA-G, and the third emission area PXA-B may have the same area in plan view.

The shapes, the areas, the arrangements of the first emission area PXA-R, the second emission area PXA-G, and the third emission area PXA-B of the display panel DP of the disclosure may be designed in various manners depending on a color of emitted light or the size and configuration of the display panel DP, and are not limited to the aspect illustrated in FIG. 2.

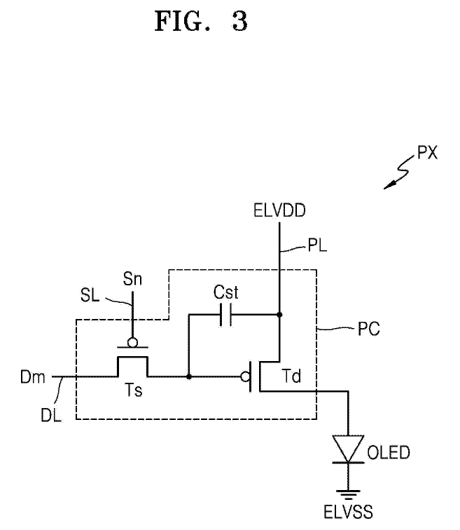

FIG. 3 is an equivalent circuit diagram of one pixel PX included in the display panel DP, according to an aspect of the disclosure.

Referring to FIG. 3, each pixel PX includes a pixel circuit PC connected to the scan line SL and the data line DL, and the organic light-emitting diode OLED connected to the pixel circuit PC.

The pixel circuit PC may include a driving thin-film transistor Td, a switching thin-film transistor Ts, and a storage capacitor Cst. The switching thin-film transistor Ts is connected to the scan line SL and the data line DL, and transmits, to the driving thin-film transistor Td, a data signal Dm input from the data line DL according to a scan signal Sn input from the scan line SL.

The storage capacitor Cst is connected to the switching thin-film transistor Ts and the driving voltage line PL, and stores a voltage corresponding to a difference between a voltage received from the switching thin-film transistor Ts and a first power voltage ELVDD supplied to the driving voltage line PL.

The second power voltage ELVSS may be a driving voltage having a relatively lower level than the first power voltage ELVDD. A level of the driving voltage supplied to each pixel PX may be a difference between levels of the first power voltage ELVDD and the second power voltage ELVSS.

The driving thin-film transistor Td may be connected to the driving voltage line PL and the storage capacitor Cst, and control a driving current flowing through the organic light-emitting diode OLED from the driving voltage line PL in response to a value of a voltage stored in the storage capacitor Cst. The organic light-emitting diode OLED may emit light of a selected luminance according to the driving current.

In FIG. 3, the pixel circuit PC includes two thin-film transistors and one storage capacitor, but the disclosure is not limited thereto. The pixel circuit PC may include two or more storage capacitors.

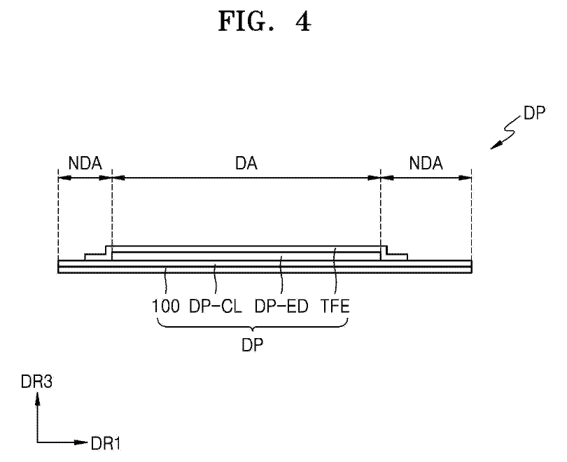

FIG. 4 is a schematic cross-sectional view taken along line I-I' of FIG. 2.

Referring to FIG. 4, the display panel DP may be a light-emitting display panel, but is not particularly limited. For example, the display panel DP may be an organic light-emitting display panel or an inorganic light-emitting display panel. An emission layer in the organic light-emitting display panel may include an organic light-emitting material. An emission layer in the inorganic light-emitting display panel may include quantum dots, quantum rods, or micro light-emitting diodes (LEDs). Hereinafter, the display panel DP is described as an organic light-emitting display panel.

The display panel DP may include the substrate 100, and a circuit element layer DP-CL, a display element layer DP-ED, and an encapsulation layer TFE, which are arranged on the substrate 100. An input sensor (not shown) may be positioned directly on the encapsulation layer TFE.

The substrate 100 may include at least one plastic film. The substrate 100 may be a flexible substrate and may include a plastic substrate, a glass substrate, a metal substrate, or an organic/inorganic composite material substrate. In the present specification, the display area DA and the non-display area NDA may be defined in the substrate 100, and in this case, configurations arranged on the substrate 100 may be arranged to overlap the display area DA or the non-display area NDA.

The circuit element layer DP-CL includes at least one insulating layer and a circuit element. The insulating layer includes at least one inorganic layer and at least one organic layer. The circuit element includes signal lines, a pixel driving circuit, and the like.

The display element layer DP-ED includes barrier ribs 260 and the light-emitting element ED. The light-emitting element ED may include the pixel electrode 410, an intermediate layer 420 including an emission layer, and the opposite electrode 430.

The encapsulation layer TFE includes a plurality of thin-films. Some thin-films are arranged to improve optical efficiency, and some thin-films are arranged to protect organic light-emitting diodes.

The input sensor may have a multilayer structure. The input sensor may include a single conductive layer or a plurality of conductive layers. The input sensor may include a single insulating layer or a plurality of insulating layers. The input sensor may detect an external input, for example, in a capacitive manner. In the disclosure, an operating method of the input sensor is not particularly limited, and in an aspect of the disclosure, the input sensor may detect an external input by using an electromagnetic induction method or a pressure detection method. In another aspect of the disclosure, the input sensor may be omitted.

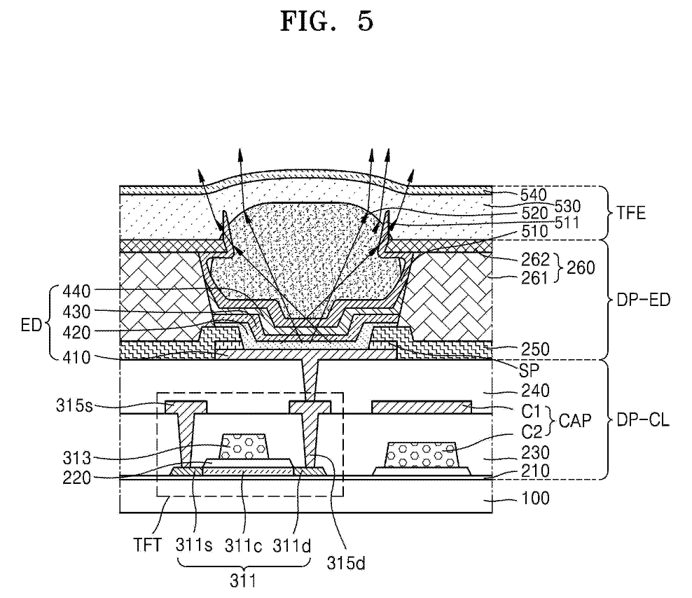

FIG. 5 is a schematic cross-sectional view taken along line II-II' of FIG. 2.

FIG. 5 is an enlarged view of one emission area in the display area DA, and the emission area may correspond to any one of the first emission area PXA-R, the second emission area PXA-G, and the third emission area PXA-B of FIG. 2. Referring to FIG. 5, the display panel DP may include the substrate 100, the circuit element layer DP-CL, the display element layer DP-ED, and the encapsulation layer TFE.

As described above, the substrate 100 may include areas corresponding to the display area DA and the non-display area NDA outside the display area, as described above. The substrate 100 may include any one of various flexible or bendable materials. For example, the substrate 100 may include glass, a metal, or a polymer resin. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. Obviously, various modifications are possible, for example, the substrate 100 may have a multilayer structure including two layers each including such a polymer resin, and a barrier layer arranged between the layers and including an inorganic material, such as silicon oxide, silicon nitride, or silicon oxynitride.

The circuit element layer DP-CL may be arranged on the substrate 100. The circuit element layer DP-CL may include a buffer layer 210, a thin-film transistor TFT, a gate insulating layer 220, an interlayer insulating layer 230, a source electrode 315s, and a drain electrode 315d.

The buffer layer 210 may be arranged on the substrate 100. The buffer layer 210 may operate as a barrier layer and/or a blocking layer to prevent diffusion of impurity ions, prevent penetration of moisture or external air, and provide a flat surface. In some aspects, the buffer layer 210 may improve a bonding strength between the substrate 100 and a semiconductor layer 311. The buffer layer 210 may include silicon oxide, silicon nitride, or silicon oxynitride. In some aspects, the buffer layer 210 may adjust a rate at which heat is provided during a crystallization process for forming the semiconductor layer 311 such that the semiconductor layer 311 may be uniformly crystallized.

The semiconductor layer 311 may be arranged on the buffer layer 210. The semiconductor layer 311 may include polysilicon. However, the semiconductor layer 311 is not limited thereto and may include amorphous silicon or metal oxide. The semiconductor layer 311 may include a channel region in which impurities are not doped, and a source region and a drain region arranged on opposite sides of the channel region and in which impurities are doped. The impurities may vary according to a type of a thin-film transistor, and may be N-type impurities or P-type impurities.

The gate insulating layer 220 may be arranged on the semiconductor layer 311. The gate insulating layer 220 may be a component securing insulation between the semiconductor layer 311 and a gate electrode 313. The gate insulating layer 220 may include an inorganic material such as silicon oxide, silicon nitride, and/or silicon oxynitride, may be arranged between the semiconductor layer 311 and a gate layer 120, and may have a single layer or multilayer structure including the above material.

In some aspects, the gate insulating layer 220 has a shape corresponding to an entire surface of the substrate 100 and may have a structure in which contact holes are formed in pre-set portions. An insulating layer including an inorganic material as such may be formed through chemical vapor deposition (CVD) or atomic layer deposition (ALD). This is also applied to aspects described below and modifications thereof.

The gate electrode 313 may be arranged on the gate insulating layer 220. The gate electrode 313 may include at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

The interlayer insulating layer 230 may be arranged on the gate electrode 313. The interlayer insulating layer 230 may cover the gate electrode 313. The interlayer insulating layer 230 may include an inorganic material. For example, the interlayer insulating layer 230 may include a metal oxide or a metal nitride, and in detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). According to some aspects, the interlayer insulating layer 230 may have a double structure of SiOₓ/SiN_{y} or SiNₓ/SiO_{y}.

The source electrode 315s and the drain electrode 315d may be located above the interlayer insulating layer 230. The source electrode 315s and the drain electrode 315d may serve as electrodes connected to the source/drain regions of the semiconductor layer 311 through contact holes defined through the interlayer insulating layer 230. The source electrode 315s and the drain electrode 315d may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the source electrode 315s and the drain electrode 315d may include a Ti layer, an Al layer, and/or a Cu layer.

A planarization layer 240 may be an organic insulating layer that covers upper portions of the source electrode 315s and the drain electrode 315d and has a generally flat upper surface, acting as a planarization film. The planarization layer 240 may include a material different from at least one inorganic insulating layer arranged there below, such as the gate insulating layer 220 and the interlayer insulating layer 230. The planarization layer 240 may include an organic insulating material. The planarization layer 240 may include an organic insulating material such as acryl, benzo cyclobutene (BCB), polyimide, or hexamethyldisiloxane (HMDSO).

The display element layer DP-ED may be arranged on the circuit element layer DP-CL. The display element layer DP-ED may include the light-emitting element ED, the pixel-defining layer 250, and the barrier ribs 260.

The light-emitting element ED may include the pixel electrode 410, the intermediate layer 420 including the emission layer, and the opposite electrode 430.

The pixel electrode 410 may be arranged in a display area, and for example, may be arranged on the planarization layer 240 of the circuit element layer DP-CL. The pixel electrode 410 may be electrically connected to the thin-film transistor TFT by coming into contact with either the source electrode 315s or the drain electrode 315d through the contact hole formed in the planarization layer 240, and the like. FIG. 5 illustrates the pixel electrode 410 being connected to the drain electrode 315d.

The pixel electrode 410 may be a transparent electrode, a semi-transparent electrode, or a reflective electrode. The pixel electrode 410 may be conductive. For example, the pixel electrode 410 may include any one of various materials as long as the pixel electrode 410 has conductivity, such as a metal, a transparent conductive oxide (TCO), or a conductive polymer material. The pixel electrode 410 may include a single layer or multiple layers. In an aspect, the pixel electrode 410 may include three layers respectively including indium tin oxide (ITO), silver (Ag), and indium tin oxide (ITO).

According to an aspect of the disclosure, the display panel DP may further include a sacrificial pattern SP. The sacrificial pattern SP may be arranged on an upper surface of the pixel electrode 410. A sacrificial opening that exposes a portion of the upper surface of the pixel electrode 410 may be defined in the sacrificial pattern SP. The sacrificial pattern SP may include an amorphous transparent conductive oxide. In an aspect of the disclosure, the sacrificial pattern SP may be omitted.

The intermediate layer 420 and the opposite electrode 430 may be arranged in an opening of the pixel-defining layer 250.

The intermediate layer 420 may be arranged on the pixel electrode 410. The intermediate layer 420 may be patterned by a tip portion defined in the barrier ribs 260. At least a portion of the intermediate layer 420 may be located in the emission area. The intermediate layer 420 may be located entirely within the emission area, or the intermediate layer 420 may be located within a barrier opening as well as within the emission area. In an aspect including the sacrificial pattern SP, the intermediate layer 420 may also be located in the sacrificial opening. The intermediate layer 420 may include the emission layer including a light-emitting material.

The intermediate layer 420 may further include a hole injection layer (HIL) and a hole transport layer (HTL) arranged between the pixel electrode 410 and the emission layer, and may include an electron transport layer (ETL) and an electron injection layer (EIL) arranged on the emission layer.

The opposite electrode 430 may be a cathode that is an electron injection electrode, and may be arranged on the intermediate layer 420. The opposite electrode 430 may be patterned by the tip portion defined in the barrier ribs 260.

The opposite electrode 430 may be conductive. For example, the opposite electrode 430 may include any one of various materials as long as the opposite electrode 430 has conductivity, such as a metal, a transparent conductive oxide (TCO), or a conductive polymer material. The opposite electrode 430 may include Li, Ag, Mg, Al, Al-Li, Ca, Mg-In, Mg-Ag, ytterbium (Yb), Ag-Yb, ITO, IZO, or any combination thereof. The opposite electrode 430 may have a single-layer structure including a single layer or a multilayer structure including a plurality of layers.

The display panel DP may further include an auxiliary electrode 440 arranged between the opposite electrode 430 and a first inorganic layer 510. The auxiliary electrode 440 may cover an upper surface of the opposite electrode 430 and at least a portion of an inner surface of a first barrier layer 261. The auxiliary electrode 440 may include a transparent conductive oxide (TCO), for example, indium tin oxide (ITO), indium zinc oxide (IZO), zinc oxide (ZnO), or indium tin zinc oxide (ITZO), and may also include Mo, Ti, or Ag.

The opposite electrode 430 and the auxiliary electrode 440 may be electrically connected to the first barrier layer 261 and a second barrier layer 262, which may include a conductive material. In the present aspect, the barrier ribs 260 may receive a bias voltage. The opposite electrode 430 may be electrically connected to the barrier ribs 260 and receive the bias voltage from the barrier ribs 260.

The pixel-defining layer 250 may be arranged on the planarization layer 240 of the circuit element layer DP-CL. The pixel-defining layer 250 may cover an edge of the pixel electrode 410 and define the emission area. The emission area may correspond to the sacrificial opening of the sacrificial pattern SP. According to the present aspect, an upper surface of the pixel electrode 410 may be spaced apart from the pixel-defining layer 250 in a cross-sectional view with the sacrificial pattern SP between the pixel electrode 410 and the pixel-defining layer 250, and thus, the pixel electrode 410 may be protected from being damaged during a process of forming the emission area.

An inner surface of the sacrificial pattern SP defining the sacrificial opening may be closer to a center of the pixel electrode 410 than to an inner surface of the pixel-defining layer 250 defining the emission area. However, an aspect is not limited thereto, and the inner surface of the sacrificial pattern SP defining the sacrificial opening may be substantially aligned with the inner surface of the pixel-defining layer 250 defining the corresponding emission area. In this case, the emission area may be viewed as an area of the pixel electrode 410, exposed from the corresponding sacrificial opening.

The pixel-defining layer 250 may include an inorganic insulating material. For example, the pixel-defining layer 250 may include silicon nitride (SiNx). The pixel-defining layer 250 may be arranged between the pixel electrode 410 and the barrier ribs 260 to block the pixel electrode 410 and the barrier ribs 260 from being electrically connected to each other.

The barrier ribs 260 may be arranged on the pixel-defining layer 250. The barrier ribs 260 may define the barrier opening. The barrier opening may correspond to the emission area and expose at least a portion of the pixel electrode 410.

In the present aspect, the barrier ribs 260 may include the first barrier layer 261 and the second barrier layer 262. The first barrier layer 261 may be arranged on the pixel-defining layer 250, and the second barrier layer 262 may be arranged on the first barrier layer 261. As shown in FIG. 5, a thickness of the first barrier layer 261 may be greater than a thickness of each second barrier layer 262, but is not limited thereto.

In the present aspect, the first barrier layer 261 may be relatively sunken compared to the second barrier layer 262 with respect to the emission area. For example, the first barrier layer 261 may be formed by being undercut with respect to the second barrier layer 262 in a cross-sectional view. The second barrier layer 262 may include a tip portion protruding from an inner surface of the first barrier layer 261 toward a center of the opening of the barrier ribs 260.

In an aspect of the disclosure, each of the first barrier layer 261 and the second barrier layer 262 may include a conductive material. For example, the conductive material may include a metal, a metal nitride, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy thereof. The metal nitride may include titanium nitride (TiN). The TCO may include indium tin oxide (ITO), indium zinc oxide (IZO), zinc oxide, indium oxide, indium gallium oxide, indium gallium zinc oxide (IGZO), or aluminum zinc oxide.

The encapsulation layer TFE may be arranged on the auxiliary electrode 440 to seal the display element layer DP-ED. The encapsulation layer TFE may include at least one inorganic layer and at least one organic layer. For example, the encapsulation layer TFE may include the first inorganic layer 510, a second inorganic layer 540, and a first organic layer 520 and a second organic layer 530, which are arranged between the first inorganic layer 510 and the second inorganic layer 540. Inorganic layers may protect the display element layer DP-ED from moisture and oxygen, and organic layers may protect the display element layer DP-ED from foreign substances such as dust particles.

The first inorganic layer 510 may be located within the barrier opening. In the present aspect, the first inorganic layer 510 may cover the opposite electrode 430, and in the present aspect, the first inorganic layer 510 may cover the upper surface of the auxiliary electrode 440 arranged in the emission area, the inner surface of the first barrier layer 261, and a lower surface and an inner surface of the tip portion of the second barrier layer 262, protruding from the inner surface of the first barrier layer 261 toward the center of the opening of the barrier ribs 260.

In the present aspect, the first inorganic layer 510 may include a material that may be formed through an atomic layer deposition (ALD) process. For example, the first inorganic layer 510 may include aluminum oxide (AlOx), hafnium oxide (HfOx), tin oxide (SnOx), zinc oxide (ZnOx), magnesium oxide (MgOx), zirconium oxide (ZrOx), silicon oxide (SiOx), or silicon nitride (SiNx).

The first inorganic layer 510 arranged in the emission area has a thin thickness of 30 nm to 100 nm through the ALD process, and thus, a water vapor transmission rate (WVTR) may be reduced by more than 100 times compared to an existing thin-film encapsulation layer, and the first inorganic layer 510 arranged on the barrier ribs 260 may be removed through etching.

The first inorganic layer 510 may include an extending portion 511 protruding further than the second barrier layer 262 in a light-emitting direction. The extending portion 511 may be formed by protruding in the light-emitting direction through a portion of the first organic layer 520 and a portion of the second organic layer 530.

The first organic layer 520 may be arranged on the first inorganic layer 510, and may have a shape that protrudes more than the second barrier layer 262 and has a curved outer surface while filling the opening of the barrier ribs 260. The first organic layer 520 may include polyimide, aryl epoxy resin, or thiophenol-based resin, but is not limited thereto as long as a refractive index of the first organic layer 520 is 1.7 or more.

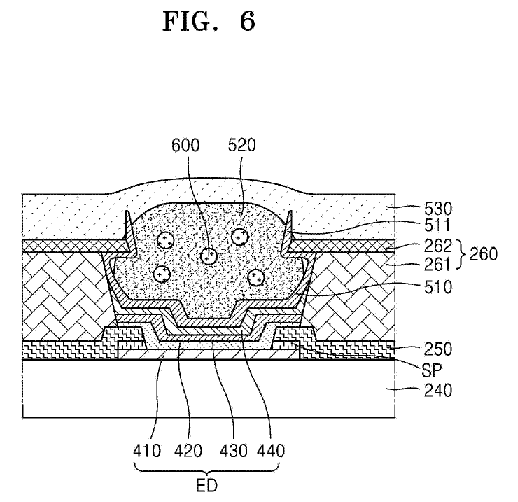

FIG. 6 is another schematic cross-sectional view taken along line II-II' of FIG. 2.

Referring to FIG. 6, the first organic layer 520 may have a scattering agent 600 dispersed therein. The scattering agent 600 may scatter light so that more light may be emitted. For example, the scattering agent 600 may increase a light-emitting efficiency. The scattering agent 600 may include any material from among metals or metal oxides, which evenly scatter light. For example, the scattering agent 600 may include at least one of TiO₂, ZrO₂, Al₂O₃, In₂O₃, ZnO, SnO₂, Sb₂O₃, or ITO.

The display panel DP may cover the entire display area DA and further include the second organic layer 530 arranged on the first organic layer 520 and the second inorganic layer 540 arranged on the second organic layer 530.

The second organic layer 530 may cover an upper surface of the first organic layer 520 and an upper surface of the second barrier layer 262. The second organic layer 530 may provide a flat upper surface. The second organic layer 530 may include a monomer-based material or a polymer-based material. Examples of the polymer-based material may include an acrylic resin, an epoxy resin, polyimide, and polyethylene. For example, the polymer-based material may include polyethylene terephthalate, polyethylene naphthalate, polycarbonate, polyimide, polyethylene sulfonate, polyoxymethylene, polyarylate, hexamethyldisiloxane, acrylic resins (e.g., polymethyl methacrylate, polyacrylic acid, etc.), and any combination thereof.

A refractive index of the first organic layer 520 may be greater than a refractive index of the first inorganic layer 510. In some aspects, the refractive index of the first inorganic layer 510 and the refractive index of the first organic layer 520 may be greater than a refractive index of the second organic layer 530.

For example, the refractive index of the first inorganic layer 510 may be more than 1.5 but less than 1.7, and the refractive index of the first organic layer 520 may be 1.7 or more. The refractive index of the second organic layer 530 may be 1.5 or less. Accordingly, light may be refracted at an interface of the first organic layer 520 and the extending portion 511 of the first inorganic layer 510, and thus, a light-emitting efficiency in an upward direction may be improved.

The second inorganic layer 540 may be arranged on the second organic layer 530 (not illustrated in FIG. 6). The first inorganic layer 510 and the second inorganic layer 540 may include one or more inorganic materials from among Al₂O₃, TiO₂, Ta₂O₅, HfO₂, zinc oxide, SiO₂, SiN_{X}, or SiON.

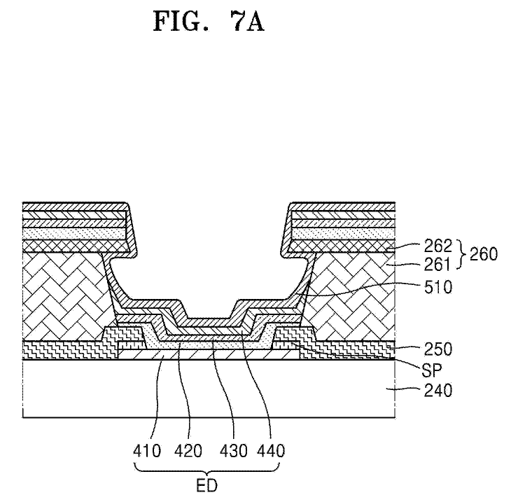

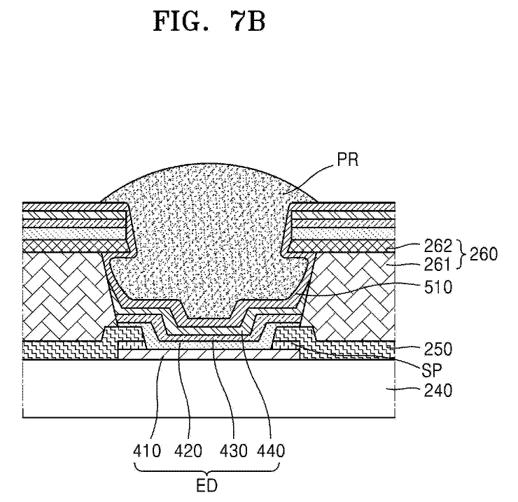

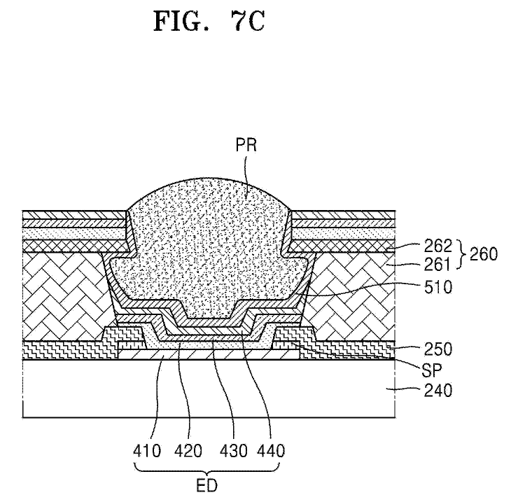

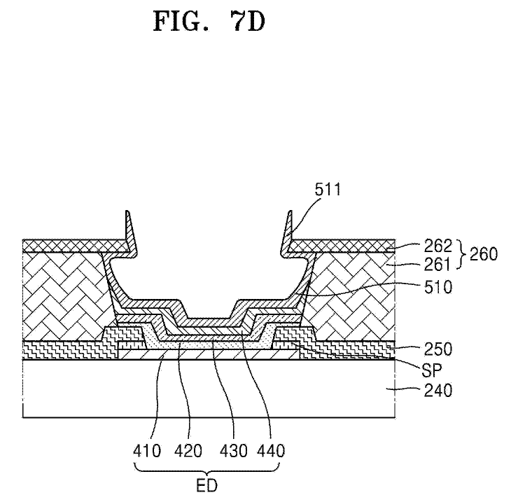

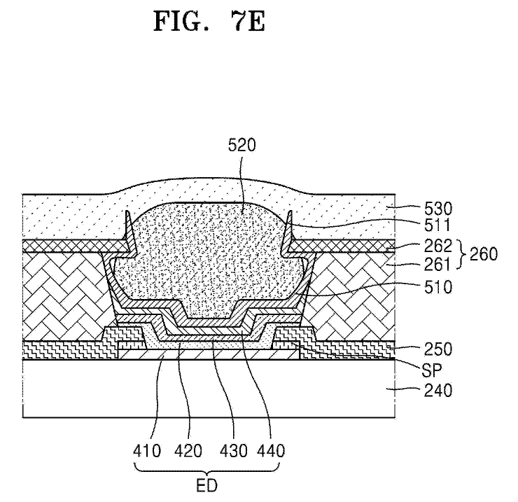

FIGS. 7A to 7E are cross-sectional views schematically illustrating a method of manufacturing the display panel DP of FIG. 1.

The method of manufacturing the display panel DP may include forming the pixel-defining layer 250 that covers the edge of the pixel electrode 410 arranged in the display area DA of the substrate 100 to define the emission area. The method further includes forming the barrier ribs 260 that are arranged on the pixel-defining layer 250. The barrier ribs 260 define the barrier opening corresponding to the emission area, and include the first barrier layer 261 and the second barrier layer 262 arranged on the first barrier layer 261. The barrier ribs 260 includes a tip portion protruding from the inner surface of the first barrier layer 261 toward the center of the barrier opening. The method further includes sequentially forming the intermediate layer 420, a layer that includes the opposite electrode 430, a layer that includes the auxiliary electrode 440, and the first inorganic layer 510 on the pixel electrode 410 and on barrier ribs 260. The method further includes forming the first organic layer 520 in the emission area. The method further includes subsequently removing the portion of the intermediate layer 420, the layer that includes opposite electrode 430, the layer that includes auxiliary electrode 440, and the first inorganic layer 510 formed on the barrier ribs 260. When the portions of the intermediate layer 420, the opposite electrode 430 and the first inorganic layer 510 formed on the barrier ribs 260 are removed, the first inorganic layer 510 may be formed to include the extending portion 511 that protrudes further than the second barrier layer 262 in the light-emitting direction.

First, the forming of the barrier ribs 260 may include forming the first barrier layer 261 on the pixel-defining layer 250 and forming the second barrier layer 262 on the first barrier layer 261. If the forming of the first barrier layer 261 and the second barrier layer 262 is performed through a deposition process of a conductive material, a sputtering deposition process may be used.

Then, the opening of the barrier ribs 260 may be formed by performing a first etch process on the first barrier layer 261 and the second barrier layer 262, by using a photoresist layer as a mask. Here, the first etch process may be a dry etch process and may be performed in an etch environment in which an etch selectivity between the first barrier layer 261 and the second barrier layer 262 is substantially the same.

Next, the opening of the barrier ribs 260 may be formed by performing a second etch process on the first barrier layer 261 and the second barrier layer 262, by using the photoresist layer as the mask. Here, the second etch process may be a wet etch process and may be performed in an environment in which the etch selectivity between the first barrier layer 261 and the second barrier layer 262 is high. Accordingly, the inner surface of the barrier ribs 260 defining a first barrier opening may have an undercut shape in a cross-sectional view.

For example, with respect to an etching solution in the second etch process, because an etch rate of the first barrier layer 261 is greater than an etch rate of each second barrier layer 262, the first barrier layer 261 may be mainly etched. Depending on conditions of the second etch process, the second barrier layer 262 may be partially etched together with the first barrier layer 261, or the second barrier layer 262 may not be etched. In case that the second barrier layer 262 is not etched, it may be seen that etching only the first barrier layer 261 is performed after the first barrier layer 261 and the second barrier layer 262 are etched.

Through the second etch process, the tip portion may be formed in the barrier ribs 260 by a portion of the second barrier layer 262 protruding from the first barrier layer 261.

The method according to the present aspect may include performing a third etch process on the pixel-defining layer 250 so that the pixel-defining layer 250 may define the emission area. The third etch process may be performed using a dry etch method and may be performed using the photoresist layer and the second barrier layer 262 as a mask.

The method according to the present aspect may include a fourth etch process on the sacrificial pattern SP. The fourth etch process may be performed using a wet etch method and may be performed using a photoresist layer and the second barrier layer 262 as a mask.

The sacrificial opening corresponding to the emission area may be formed in the sacrificial pattern SP. At least a portion of the pixel electrode 410 may be exposed from the sacrificial pattern SP and the pixel-defining layer 250, by the sacrificial opening and the emission area.

A process of etching the sacrificial pattern SP may be performed in an environment in which an etch selectivity between the sacrificial pattern SP and the pixel electrode 410 is high, thereby preventing the pixel electrode 410 from being etched together. For example, by arranging the sacrificial pattern SP having a higher etch rate than the pixel electrode 410 between the pixel-defining layer 250 and the pixel electrode 410, the pixel electrode 410 may be prevented from being etched together and damaged during an etch process.

The forming of the intermediate layer 420 including the emission layer, the opposite electrode 430, the auxiliary electrode 440, and the first inorganic layer 510 on the pixel electrode 410 after the photoresist layer is removed may be performed through a deposition process. In an aspect, the forming of the emission layer may be performed through a thermal evaporation process, the forming of the opposite electrode 430 may be performed through a sputtering process, and the forming of the auxiliary electrode 440 may be performed through a thermal evaporation process, but an aspect is not limited thereto.

The forming of the first inorganic layer 510 may be performed through an ALD process to cover the lower surface and the inner surface of the tip portion (see FIG. 7A). Accordingly, the first inorganic layer 510 arranged in the emission area has a thin thickness of 30 nm to 100 nm through the ALD process, and thus, a WVTR may be reduced by more than 100 times compared to an existing thin-film encapsulation layer, and the first inorganic layer 510 arranged on the barrier ribs 260 may be removed through etching.

Referring to FIG. 7A, when forming the intermediate layer 420 including the emission layer, the opposite electrode 430, and the auxiliary electrode 440, layers deposited that include the intermediate layer 420 including the emission layer, the opposite electrode 430, and the auxiliary electrode 440 may be separated by the tip portion defined in the barrier ribs 260 so that these layers are arranged in the emission area and on the second barrier layer 262 as separated layers.

Referring to FIG. 7B, the photoresist layer (PR) is formed in the emission area and protrudes further than the second barrier layer 262 in the light-emitting direction.

Referring to FIG. 7C, the first inorganic layer 510 arranged on the second barrier layer 262 may be removed by performing a fifth dry or wet etch process. Referring to FIG. 7D, the portions of the layers that include intermediate layer 420 including the emission layer, the opposite electrode 430, and the auxiliary electrode 440 which are arranged on the second barrier layer 262 may be removed by performing a sixth wet etch process.

Referring to FIG. 7D, after the sixth etch process, the first inorganic layer 510 may include the extending portion 511 protruding further than the second barrier layer 262 in the light-emitting direction. .

Referring to FIG. 7E, the method may further include forming a first organic layer 520 in the emission area and forming the second organic layer 530 on the first organic layer 520 such that the extending portion 511 protrudes in the light-emitting direction through a portion of the first organic layer 520 and a portion of the second organic layer 530. The method may further include forming the second inorganic layer 540 on the second organic layer 530 (not illustrated). The second organic layer 530 may be formed by applying an organic material using an inkjet method, but is not limited thereto. The second organic layer 530 may provide a flat upper surface. Then, the second inorganic layer 540 may be formed by performing a chemical vapor deposition (CVD) process using an inorganic material. Accordingly, the display panel DP including the substrate 100, the circuit element layer DP-CL, the display element layer DP-ED, and the encapsulation layer TFE may be formed.

The display panel DP according to the present aspect may be applied to any one of various electronic devices 10. The electronic device 10 according to an aspect may include the display panel DP described above, and further include a module or device having other additional functions, in addition to the display panel DP.

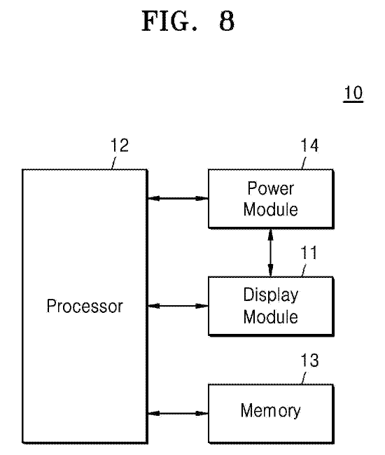

FIG. 8 is a block diagram of the electronic device 10 according to an aspect of the disclosure.

Referring to FIG. 8, the electronic device 10 according to an aspect may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for operations of the processor 12 or the display module 11. In case that the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module configured to convert power supplied by the power supply module to generate power required for operations of the electronic device 10.

At least one of the components of the electronic device 10 may be included in a display device according to the above-described aspects. Some of individual modules functionally included in one module may be included in the display device and others may be provided separately from the display device. For example, the display device may include the display module 11, and the processor 12, the memory 13, and the power module 14 may be provided in the form of other devices in the electronic device 10 other than the display device.

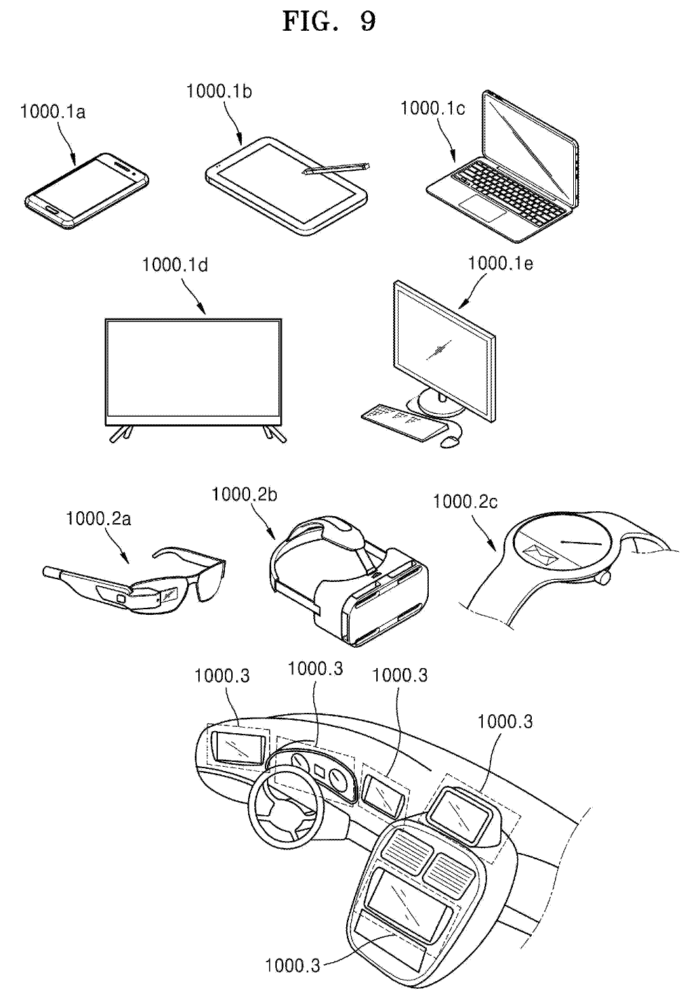

FIG. 9 is a schematic diagram of electronic devices according to various aspects, including the display panel DP of FIG. 1.

Referring to FIG. 9, various electronic devices to which a display device according to aspects is applied may include not only image display electronic devices, such as a smartphone 10_1a, a tablet personal computer (PC) 10_1b, a laptop PC 10_1c, a television (TV) 10_1d, and a desk monitor 10_1e, but also wearable electronic devices, such as smart glasses 10_2a, a head-mount display 10_2b, and a smart watch 10_2c, and vehicle electronic devices 10_3 including display modules such as a dashboard of a vehicle, a center fascia, a center information display (CID) provided on a dashboard, and a room mirror display.

An electronic device 10 including a display panel according to an aspect of the disclosure may have improved reliability by blocking a path through which moisture and/or oxygen may penetrate using the first inorganic layer formed through an atomic layer deposition (ALD) method.

An electronic device 10 including a display panel according to an aspect of the disclosure may have improved light-emitting efficiency due to the difference in refractive indexes between the first organic layer and the extending portion of the first inorganic layer.

It should be understood that aspects described herein should be considered in a descriptive sense only and not for purposes of limitation. Descriptions of features or aspects within each aspect should typically be considered as available for other similar features or aspects in other aspects.

While one or more aspects have been described with reference to the figures, it will be understood by those of ordinary skill in the art that various changes in form and details may be made therein without departing from the spirit and scope of the disclosure.

What is claimed is:

1. A display panel configured to emit light in a light-emitting direction, the display panel comprising:
a display element arranged in a display area and including a pixel electrode electrically connected to a thin-film transistor, an opposite electrode arranged on the pixel electrode, and an intermediate layer arranged between the pixel electrode and the opposite electrode, the intermediate layer including an emission layer;
a pixel-defining layer covering an edge of the pixel electrode and defining an emission area;
barrier ribs including a first barrier layer arranged on the pixel-defining layer and a second barrier layer arranged on the first barrier layer, the barrier ribs defining a barrier opening corresponding to the emission area;
a first inorganic layer arranged in the emission area; and
a first organic layer arranged on the first inorganic layer,
wherein the second barrier layer includes a tip portion protruding in a direction from an inner surface of the first barrier layer to a center of the barrier opening, and
the first inorganic layer includes an extending portion protruding further than the second barrier layer in the light-emitting direction.

2. The display panel of claim 1, wherein the barrier ribs include a conductive material.

3. The display panel of claim 1, wherein the first inorganic layer covers a lower surface and an inner surface of the tip portion.

4. The display panel of claim 1, wherein the first inorganic layer includes aluminum oxide (AlOx), hafnium oxide (HfOx), tin oxide (SnOx), zinc oxide (ZnOx), magnesium oxide (MgOx), zirconium oxide (ZrOx), silicon oxide (SiOx), or silicon nitride (SiNx).

5. The display panel of claim 1, wherein a thickness of the first inorganic layer arranged in the emission area is about 30 nm to about 100 nm.

6. The display panel of claim 1, wherein a refractive index of the first organic layer is greater than a refractive index of the first inorganic layer.

7. The display panel of claim 1, wherein a refractive index of the first inorganic layer is more than 1.5 but less than 1.7, and a refractive index of the first organic layer is 1.7 or more.

8. The display panel of claim 1, further comprising an auxiliary electrode arranged between the opposite electrode and the first inorganic layer.

9. The display panel of claim 1, wherein the first organic layer includes polyimide, aryl epoxy resin, or thiophenol-based resin.

10. The display panel of claim 1, wherein the first organic layer protrudes more than the second barrier layer in the light-emitting direction, the first organic layer has a curved outer surface.

11. The display panel of claim 1, wherein a scattering agent is dispersed within the first organic layer.

12. The display panel of claim 1, further comprising:
a second organic layer entirely covering the display area and arranged on the first organic layer; and
a second inorganic layer arranged on the second organic layer.

13. The display panel of claim 12, wherein a refractive index of the first inorganic layer is greater than a refractive index of the second organic layer.

14. The display panel of claim 12, wherein a refractive index of the second organic layer is 1.5 or less.

15. A method of manufacturing a display panel, the method comprising: forming a pixel-defining layer covering an edge of a pixel electrode that is arranged in a display area, the pixel-defining layer defining an emission area;
forming barrier ribs on the pixel-defining layer, the barrier ribs defining a barrier opening corresponding to the emission area, the barrier ribs including a first barrier layer and a second barrier layer arranged on the first barrier layer, the second barrier layer including a tip portion protruding in a direction from an inner surface of the first barrier layer to a center of the barrier opening;
sequentially forming an intermediate layer, an opposite electrode layer, and a first inorganic layer on the pixel electrode, and
removing portions of the intermediate layer, the opposite electrode layer, and the first inorganic layer formed on the barrier ribs so that the first inorganic layer forms an extending portion that protrudes further than the second barrier layer in a light-emitting direction; and
forming a first organic layer filling the barrier opening.

16. The method of claim 15, wherein the first inorganic layer covers a lower surface and inner surface of the tip portion.

17. The method of claim 15, wherein forming the first inorganic layer comprises using an atomic layer deposition (ALD) method.

18. The method of claim 15, further comprising:
forming a second organic layer on the first organic layer; and
forming a second inorganic layer on the second organic layer.

19. The method of claim 18, wherein forming the second inorganic layer on the second organic layer comprises using a chemical vapor deposition (CVD) method.

20. An electronic device comprising:
a display device including a display panel configured to generate an image and emit light in a light-emitting direction; a processor; a memory; and a power module,
wherein the display panel comprises:
a display area;
a display element arranged in the display area, the display element including a pixel electrode electrically connected to a thin-film transistor, an opposite electrode arranged on the pixel electrode, and an intermediate layer arranged between the pixel electrode and the opposite electrode, the intermediate layer including an emission layer;
a pixel-defining layer covering an edge of the pixel electrode and defining an emission area;
barrier ribs including a first barrier layer arranged on the pixel-defining layer and a second barrier layer arranged on the first barrier layer, the barrier ribs defining a barrier opening corresponding to the emission area;
a first inorganic layer arranged in the emission area; and
a first organic layer arranged on the first inorganic layer,
wherein the second barrier layer includes a tip portion protruding in a direction from an inner surface of the first barrier layer to a center of the barrier opening, and
the first inorganic layer includes an extending portion protruding further than the second barrier layer in the light-emitting direction.
